(19) United States
(12) Patent Application Publication
(10) Pub. No.: US 2023/0402258 A1
(43) Pub. Date: Dec. 14, 2023

(54) PLASMA PROCESSING APPARATUS

(71) Applicant: SAMSUNG ELECTRONICS CO., LTD., Suwon-si (KR)

(72) Inventors: Yunhwan KIM, Suwon-si (KR); Dougyong SUNG, Suwon-si (KR); Namkyun KIM, Suwon-si (KR); Minsung KIM, Suwon-si (KR); Youngjin NOH, Suwon-si (KR)

(21) Appl. No.: 18/136,448

(22) Filed: Apr. 19, 2023

(30) Foreign Application Priority Data
Jun. 9, 2022 (KR) 10-2022-0070316

(51) Int. Cl. H01J 37/32; H01L 21/683; B33Y 80/00

(52) U.S. Cl. CPC H01J 37/32449; H01J 37/32724; H01J 37/32568; H01J 37/32082; H01L 21/6833; B33Y 80/00; H01J 2237/2007; H01J 2237/032; H01J 2237/334; H01J 2237/2001

(57) ABSTRACT

A plasma processing apparatus includes a process chamber in which a substrate processing process is performed; an electrostatic chuck having a microcavity; a lower electrode disposed to be in contact with a lower surface of the electrostatic chuck; a high-frequency power supply applying high-frequency power to the lower electrode; a conductive supporter disposed to be spaced apart from a lower portion of the lower electrode and grounded thereto; and a discharge suppressor located between the lower electrode and the conductive supporter, having a gas supply flow path forming a portion of a gas supply line, and molded by three dimensional printing, wherein the gas supply flow path has a space portion having a length of 5 mm or less in a direction of an electric field formed by the high-frequency power and connecting upper and lower surfaces of the discharge suppressor.

### CROSS-REFERENCE TO RELATED APPLICATIONS

This application claims benefit of priority to Korean Patent Application No. 10-2022-0070316, filed on Jun. 9, 2022, in the Korean Intellectual Property Office, the disclosure of which is incorporated herein by reference in its entirety.

### BACKGROUND

### 1. Field

Embodiments relate to a plasma processing apparatus.

### 2. Description of the Related Art

In general, a semiconductor device is manufactured through a plurality of unit processes including, e.g., a thin film deposition process, an etching process, or a cleaning process. The etching process may be performed in a plasma processing apparatus in which a plasma reaction is induced.

### SUMMARY

According to embodiments, a plasma processing apparatus may include a process chamber in which a substrate processing process is performed; an electrostatic chuck having a microcavity in which heat transfer gas is stored in a region on which a substrate is seated; a lower electrode disposed to be in contact with a lower surface of the electrostatic chuck; a high-frequency power supply applying high-frequency power to the lower electrode; a conductive supporter disposed to be spaced apart from a lower portion of the lower electrode and grounded thereto; and a discharge suppressor located between the lower electrode and the conductive supporter, having a gas supply flow path forming a portion of gas supply lines to which the heat transfer gas is supplied, and molded by three dimensional (3D) printing, wherein the gas supply flow path of the discharge suppressor has a space portion having substantially a length of 5 mm or less in a direction of an electric field formed by the high-frequency power and connecting upper and lower surfaces of the discharge suppressor.

According to embodiments, a plasma processing apparatus may include an electrostatic chuck supporting a substrate; a lower electrode below the electrostatic chuck; a high-frequency power supply applying high-frequency power to the lower electrode; a conductive supporter disposed to be spaced apart from a lower portion of the lower electrode and grounded thereto; and a discharge suppressor located between the lower electrode and the conductive supporter and suppressing discharge of heat transfer gas supplied to the substrate supported by the electrostatic chuck, wherein the discharge suppressor is integrally molded by three dimensional (3D) printing, and has a gas supply flow path on a gas supply path supplying the heat transfer gas and having a seamless inner wall.

According to embodiments, a plasma processing apparatus may include a process chamber; an upper electrode above the process chamber; a lower electrode below the process chamber to correspond to the upper electrode; an electrostatic chuck supporting a substrate and having a microcavity in which heat transfer gas is stored, the electrostatic chuck being on the lower electrode; a conductive supporter disposed to be spaced apart from a lower portion of the lower electrode and grounded thereto; and a discharge suppressor located between the lower electrode and the conductive supporter, and disposed on a heat transfer gas supply path supplying heat transfer gas to the microcavity; wherein the discharge suppressor has a body portion and a gas supply flow path penetrating through the body portion and forming the gas supply path, and the gas supply flow path of the discharge suppressor has a space portion having substantially a length of 5 mm or less in a direction of an electric field.

### BRIEF DESCRIPTION OF DRAWINGS

Features will become apparent to those of skill in the art by describing in detail exemplary embodiments with reference to the attached drawings, in which:

FIG. 1 is a cross-sectional view schematically illustrating a plasma processing apparatus according to an example embodiment.

FIG. 2 is a perspective view of the discharge suppressor of FIG. 1.

FIG. 3 is a side view of the discharge suppressor in a Z-axis direction of FIG. 2.

FIG. 4 is an enlarged portion of part B of FIG. 3 illustrating conceptional diagram of an action of a discharge suppressor in a gas supply flow path.

FIGS. 5 to 10 are various modified examples of the discharge suppressor according to an example embodiment.

### DETAILED DESCRIPTION

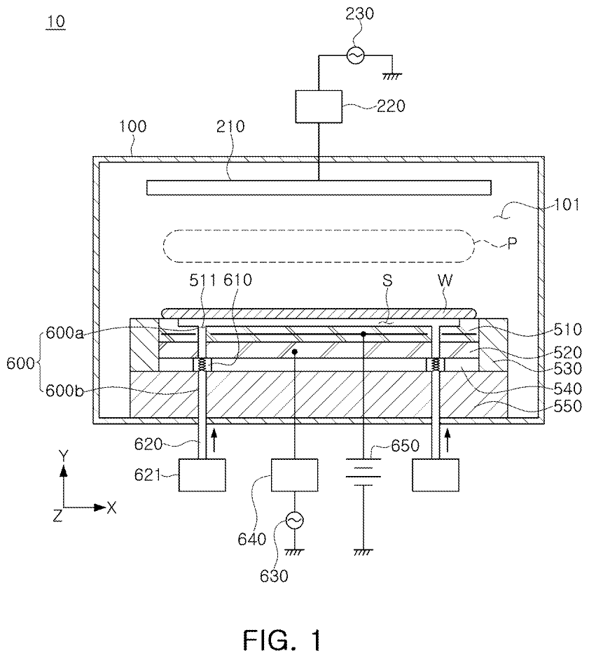

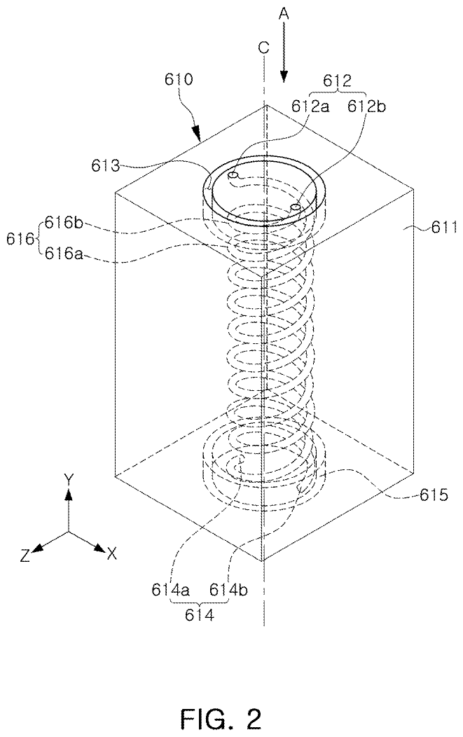

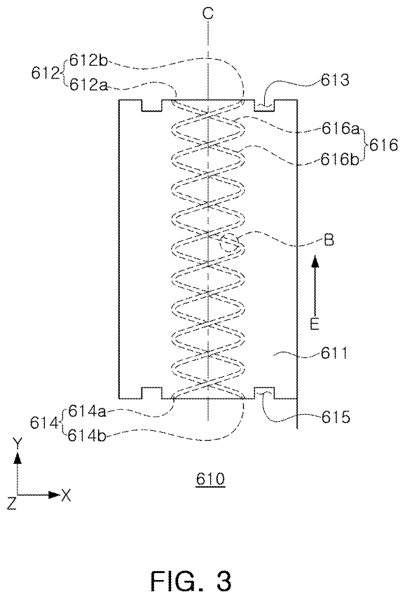

Referring to FIGS. 1 to 3, a plasma processing apparatus 10 according to an example embodiment will be described with reference to FIGS. 1 to 3. FIG. 1 is a cross-sectional view schematically illustrating a plasma processing apparatus according to an example embodiment, FIG. 2 is a perspective view of the discharge suppressor of FIG. 1, and FIG. 3 is a side view of the discharge suppressor viewed from the Z-axis direction of FIG. 2.

Referring to FIG. 1, the plasma processing apparatus 10 according to an example embodiment may include a process chamber 100. The plasma processing apparatus 10y further include a lower electrode 520, an upper electrode 210, an electrostatic chuck 510, a conductive supporter 550, and a discharge suppressor 610 in the process chamber 100.

The process chamber 100 may have an internal space 101, and plasma P may be formed in the internal space 101, so that a plasma processing process for a substrate W, an object to be treated, may be performed. For example, the plasma processing process may be an etching process.

The lower electrode 520 and the upper electrode 210 may be disposed in the internal space 101 of the process chamber 100. The lower electrode 520 and the upper electrode 210 may be a pair of parallel plate-type electrodes. The lower electrode 520 may be disposed at a bottom portion of the process chamber 100. The upper electrode 210 may be disposed at a top portion of the process chamber 100 to face the lower electrode 520, e.g., the lower electrode 520 and the upper electrode 210 may be spaced apart from each other to parallel each other and be on opposite internal surfaces of the process chamber 100.

RF power may be applied to the upper electrode 210 through a high-frequency power supply 230 and an impedance matcher 220. The lower electrode 520 may be disposed to be spaced apart from the upper electrode 210 by a predetermined interval, and may be connected to a high-frequency power supply 630 through a matcher 640. When processing the substrate W, high-frequency power, e.g., 60 MHz or 400 kHz, is supplied to the lower electrode 520 by the high-frequency power supply 630.

The lower electrode 520 may be installed on a bottom surface of the process chamber 100 through the conductive supporter 550, e.g., the conductive supporter 550 may be between the lower electrode 520 and the bottom surface of the process chamber 100. A cooling means, e.g., equipment, and a heating means, e.g., equipment, for adjusting the substrate W to a predetermined temperature may be provided inside the lower electrode 520. In addition, the electrostatic chuck 510 serving as a holder for holding the substrate W, e.g., a semiconductor wafer, may be installed on an upper surface of the lower electrode 520, e.g., the lower electrode 520 may be between the electrostatic chuck 510 and the conductive supporter 550.

The electrostatic chuck 510 for holding, e.g., supporting, the substrate W may be installed on the upper surface of the lower electrode 520. For example, the lower electrode 520 may be disposed to be in contact with a lower surface of the electrostatic chuck 510. For example, the electrostatic chuck 510 may be formed to have a substantially same shape and size as that of the substrate W to be mounted on the upper surface thereof. For example, when the substrate W is a semiconductor wafer, the electrostatic chuck 510 may have a cylindrical shape similar to that of the semiconductor wafer, and a diameter of an upper surface of the cylindrical shape facing the substrate W may be formed to be substantially similar to a diameter of the substrate W. The electrostatic chuck 510 may include a conductive member therein, and the conductive member may be connected to a high-voltage DC power supply 650 to apply a high voltage to adsorb and hold the substrate W. In this case, the electrostatic chuck 510 may hold the substrate W by a mechanical force or the like, in addition to an electrostatic force.

The conductive supporter 550 may be disposed below the lower electrode 520 to be spaced apart from each other. The conductive supporter 550 may be grounded, and disposed to be in contact with the bottom surface of the process chamber 100. For example, as illustrated in FIG. 1, an insulator 540 may be disposed between the conductive supporter 550 and the lower electrode 520. In another example, an empty space may be formed between the conductive supporter 550 and the lower electrode 520. A side surface of the lower electrode 520 may be disposed to be surrounded by a ring-shaped insulator 530, and the ring-shaped insulator 530 may be on the conductive supporter 550 and extend upwardly to cover a side surface of the electrostatic chuck 510.

A plurality of gas supply paths 511 may be provided in the electrostatic chuck 510, and the gas supply paths 511 may be connected to a gas supply line 600 penetrating through the lower electrode 520, the insulator 540, and the conductive supporter 550. For example, as illustrated in FIG. 1, the gas supply line 600 may include an upper gas supply line 600a and a lower gas supply line 600b. The upper gas supply line 600a may be connected to the gas supply paths 511 and extend through the electrostatic chuck 510 and the lower electrode 520. The lower gas supply line 600b may extend through the conductive supporter 550. The upper and lower gas supply lines 600a and 600b may be in fluid communication with each in the insulator 540.

The gas supply line 600 may be connected to a gas supply hose 620, which is external with respect to the process chamber 100 and is connected to a gas supply source 622 supplying heat transfer gas. For example, as illustrated in FIG. 1, the lower gas supply line 600b may be connected to the gas supply hose 620. A microcavity S, in which heat transfer gas is temporarily stored, may be formed on the upper surface of the electrostatic chuck 510 that faces the substrate W. The microcavity S may be disposed to overlap the substrate W.

For example, the heat transfer gas may be an inert gas, e.g., helium gas or argon gas. In another example, the heat transfer gas may be the same gas as the gas used in the plasma processing, e.g., SF₆ gas, CHF₃ gas, a mixture of CHF₃ and CO gas, or the like. In an example embodiment, a case in which helium gas is used as the heat transfer gas will be described as an example.

The heat transfer gas may be supplied from the gas supply source 622 through the heat transfer gas supply line 600 to the microcavity S provided on the upper surface of the electrostatic chuck 510 through the gas supply paths 511 of the electrostatic chuck 510. The heat transfer gas may facilitate heat transfer between the substrate W and the electrostatic chuck 510 during a plasma processing process to maintain a temperature of the substrate W at an appropriate level.

However, during the plasma processing process, when DC high-voltage power is applied to the electrostatic chuck 510 and high-frequency power is applied to the lower electrode 520 to fix the substrate W, an electric field is formed by a potential difference between the electrostatic chuck 510 and the grounded conductive supporter 550. This electric field may also potentially affect the gas supply line 600 penetrating through the lower electrode 520, the insulator 540, and the conductive supporter 550. When the gas supply line 600 is affected by the electric field, electrons included in the heat transfer gas flowing through the gas supply line 600 are accelerated in the direction of the electric field, and in this process, when the accelerated electrons collide with molecules (e.g., helium molecules) of neutral gas (e.g., helium gas) included in the heat transfer gas, the neutral gas is ionized and an electron avalanche occurs. As a result, discharge may occur in the gas supply line 600.

As described above, a discharge generated in a gas supply line may affect plasma by destabilizing matching of the plasma processing apparatus. Accordingly, the quality of the etching process may be affected. In addition, the discharge phenomenon may damage the gas supply line, prevent the substrate from being stably adsorbed to the electrostatic chuck, or damage the plasma processing apparatus.

In contrast, according to embodiments, the plasma processing apparatus 10 includes a discharge suppressor 610 on the gas supply line 600 to prevent discharge in a path through which heat transfer gas is supplied. In detail, as illustrated in FIG. 1, the discharge suppressor 610 may be disposed between the lower electrode 520 and the conductive supporter 550. An upper surface of the discharge suppressor 610 may be disposed to be in, e.g., direct, contact with a lower surface of the lower electrode 520. In addition, a lower surface of the discharge suppressor 610 may be disposed to be in, e.g., direct, contact with an upper surface of the conductive supporter 550.

The discharge suppressor 610 according to an example embodiment will be described with reference to FIGS. 2 and 3. FIG. 2 is a perspective view of the discharge suppressor 610, and FIG. 3 is a side view of the discharge suppressor viewed in the Z-axis direction of FIG. 2.

Referring to FIGS. 2 and 3, the discharge suppressor 610 may include a body portion 611 having a rectangular column shape, a gas discharge port 612 disposed on an upper surface of the body portion 611, a gas supply port 614 disposed on a lower surface of the body portion 611, and a gas supply flow path 616 connecting the gas supply port 614 and the gas discharge port 612 and through which heat transfer gas passes. According to an example embodiment, an upper groove portion 613 and a lower groove portion 615 for coupling the gas supply line 600 may be respectively disposed at a periphery of the gas supply port 614 and the gas discharge port 612.

Each of the gas discharge ports 612 and the gas supply ports 614 may be provided in plural. In an example embodiment, a case in which first and second gas discharge ports 612a and 612b and first and second gas supply ports 614a and 614b are disposed in the body portion 611 will be described as an example. The gas discharge port 612 may be connected to the upper gas supply line 600a, and the gas supply port 614 may be connected to the lower gas supply line 600b (FIG. 1), e.g., so the upper and lower gas supply lines 600a and 600b may be connected to each other through the discharge suppressor 610.

For example, the body portion 611 may be formed of an insulating material, e.g., a resin such as polyether ether ketone (PEEK). The body portion 611 may be formed of a single material. According to an example embodiment, the body portion 611 may also be formed of materials having different dielectric constants. For example, a first region of the body portion 611 may be formed of a first material having a first dielectric constant, and a second region of the body portion 611 may be formed of a second material having a second dielectric constant. In this case, the first region and the second region may be disposed to have a clear boundary, but in some example embodiments, the first material and the second material may be mixed between the first region and the second region so that a region in which the first material and the second material are mixed and the boundary is not clear may be included between the first region and the second region. In an example embodiment, although it is described that the body portion 611 is a square pillar, embodiments are not limited thereto, and the body portion 611 may be formed into various shapes, e.g., a cylindrical shape.

One or more gas supply flow paths 616 may be formed to penetrate through upper and lower surfaces of the body portion 611. The gas supply flow path 616 may form a portion of gas supply line 600, and supply heat transfer gas flowing thereinto from the lower gas supply line 600b to the upper gas supply line 600a. The gas supply flow path 616 may be formed in a shape of a seamless through hole, e.g., a continuous and uniform channel or conduit through the body portion 611 with smooth and unbroken inner sidewalls. For example, as illustrated in FIGS. 2-3, the gas supply flow path 616 may extend through an entire thickness of the body portion 611 in the Y-direction, e.g., from the upper surface of the body portion 611 to the lower surfaces of the body portion 611.

For example, a plurality of gas supply flow paths 616 may be formed to correspond to the number of gas discharge ports 612 and the gas supply ports 614, e.g., one-to-one correspondence. In another example, one gas supply flow path 616 may be disposed and each of the gas discharge port 612 and the gas supply port 614 may be provided in plural, or a plurality of gas supply flow paths may be disposed in plural and each of the gas discharge port 612 and the gas supply port 614 may be provided in plural. In an example embodiment, a case in which the body portion 611 includes a first gas supply flow path 616a and a second gas supply flow path 616b, and the first gas supply flow path 616a is connected to the first gas discharge port 612a and a first gas supply port 614a, and the second gas supply flow path 616b is connected to the second gas discharge port 612b and a second gas supply port 614b will be described as an example.

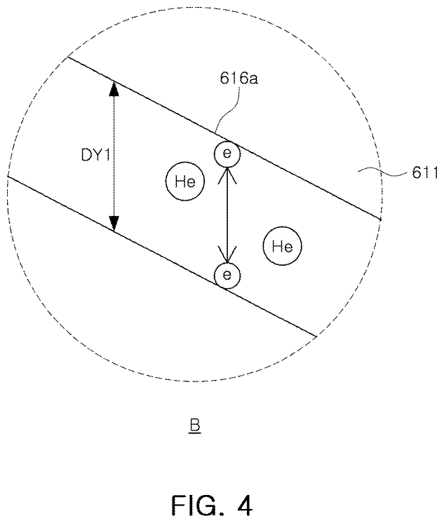

Referring to FIGS. 3 and 4, the gas supply flow path 616 may have a uniform diameter. However, embodiments are not limited thereto, e.g., a diameter of the gas supply flow path 616 may gradually increase or decrease in the Y-direction, which is a direction of the electric field E.

The gas supply flow path 616 may be formed to have only a space portion having a substantial length DY1 of 5 mm or less in the Y direction, which is a direction of the electric field E. As illustrated in FIG. 4, the length DY1 of the gas supply flow path 616 in the direction of the electric field as meant herein, does not mean a diameter of the gas supply flow path 616, but moves a length of a cross-section of the gas supply flow path 616 in the direction of the electric field E, e.g., the length DY1 is measured between sidewalls of the gas supply flow path 616 along the Y-direction (i.e., along the direction of the electric field E and the arrows in FIG. 4) which is not necessarily perpendicular to the sidewalls of the gas supply flow path 616. Accordingly, the electrons included in the heat transfer gas flowing along the gas supply flow path 616 cannot be accelerated while moving a movement path exceeding 5 mm in the direction of the electric field E. For example, referring to FIG. 4, since the accelerating electrons move along the direction of the electric field E (i.e., along the arrows in FIG. 4), the path of the electrons may be limited by the sidewalls of the gas supply flow path 616 (i.e., to the length DY1 of 5 mm or less), and therefore, the acceleration of the electrons may be slowed down after collisions with the sidewalls of the gas supply flow path 616.

In detail, as illustrated in FIG. 4, in the gas supply flow path 616 included in the discharge suppressor 610 of an example embodiment, since a distance through which electrons may move in the direction of the electric field E is limited, the electrons may collide with an inner wall of the gas supply flow path 616 and energy is lost, so that acceleration may be suppressed. As described above, since the acceleration of electrons included in the heat transfer gas is suppressed, it is possible to prevent neutral gas of the heat transfer gas from being ionized and discharged. The gas supply flow path 616 may be variously deformed within a limit having substantially a length DY1 of 5 mm or less along the Y-direction, which is the direction of the electric field E.

In general, if a gas supply flow path were to have a space portion having a length exceeding 5 mm in the direction of the electric field E, e.g., if the gas supply flow path were to extend in a linear space parallel to the direction of the electric field E, electrons included in the heat transfer gas would have accelerated in the direction of the electric field and collided with molecules of neural gas included in the heat transfer gas to generate an electron avalanche. Consequently, discharge could have been generated inside such a gas supply flow path.

In contrast, according to example embodiments, the gas supply flow path 616 includes at least one through hole shaped as a coil with space portions (i.e., length DY1) of 5 mm or less. For example, as illustrated in FIG. 3, the first gas supply flow path 616a and the second gas supply flow path 616b according to an example embodiment may be formed to form a double helix with respect to the central axis C.

The discharge suppressor 610 may be manufactured by three dimensional (3D) printing. Accordingly, in the discharge suppressor 610 according to an example embodiment, the body portion 611 may be integrally formed, and the gas supply flow path 616 formed inside the body portion 611 may be smoothly formed without a seam. For example, the gas supply flow path 616 may be integrally and smoothly formed inside the body portion 611. For example, a space with the form (e.g., shape) of a double helix (e.g., the gas supply flow path 616) may be formed through the body portion 611 via the 3D printing to form a uniform and seamless through-hole (e.g., having smooth and unbroken inner surfaces of sidewalls along its entire length between upper and lower surfaces of the discharge suppressor 610) through the body portion 611 as an integrated structure. Various types of 3D printing techniques, e.g., a fused deposition modeling (FDM) method, an electron beam freeform fabrication (EBF) method, a selective laser sintering (SLS) method, and/or a stereo lithography apparatus (SLA) method, may be implemented to form the discharge suppressor 610.

In the related art, in order to suppress occurrence of a discharge phenomenon in a gas supply line, a discharge suppressor consisting of an outer cylinder and an inner cylinder coupled to the outer cylinder, and a gas supply flow path on a surface of the inner cylinder has been proposed. However, when the discharge suppressor is formed by being divided into an outer cylinder and an inner cylinder, micro-gaps are inevitably generated between the outer cylinder and the inner cylinder due to tolerances in the manufacturing process, and these micro-gaps are disposed parallel to the direction of the electric field (E), so that a discharge occurs in such micro-gaps. Since the discharge suppressor 610, according to example embodiments, is manufactured by 3D printing, the body portion 611 may be integrally formed with the gas supply flow path 616 without seams or micro-gaps. Accordingly, in the discharge suppressor 610 according to an example embodiment, since micro-gaps that cause discharge are not formed, occurrence of discharge, e.g., due micro-gaps, may be prevented or substantially minimized.

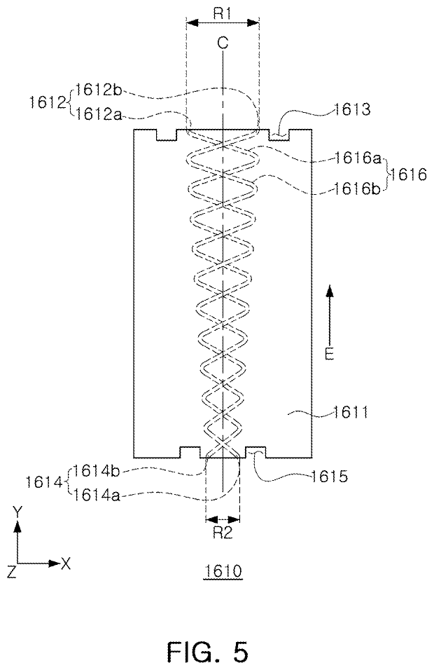

Next, various modifications of a discharge suppressor according to an example embodiment will be described with reference to FIGS. 5 to 10. FIGS. 5 to 10 are various modified examples of the discharge suppressor according to an example embodiment.

Referring to FIG. 5, a discharge suppressor 1610 according to an example embodiment has a body portion 1611, a gas discharge port 1612 may be provided on an upper surface of the body portion 1611, a gas supply port 1614 may be provided on a lower surface of the body portion 1611, and a gas supply flow path 1616 for connecting the gas supply port 1614 and the gas discharge port 1612 may be formed in the body portion 1611. An upper groove portion 1613 and a lower groove portion 1615 for coupling the gas supply line may be disposed around the gas supply port 1614 and the gas discharge port 1612, respectively. The discharge suppressor 1610 according to an example embodiment is similar to the above-described embodiment in that the gas supply flow path 1616 includes a first gas supply flow path 1616a and a second gas supply flow path 1616b, and forms a double helix with respect to a central axis C, but is different therefrom in that, in the double helix formed by the first gas supply flow path 1616a and the second gas supply flow path 1616b, an upper diameter R1 is greater than a lower diameter R2. Accordingly, a rotational radius of the first gas supply flow path 1616a and the second gas supply flow path 1616b may gradually decrease toward the lower surface of the body portion 1611.

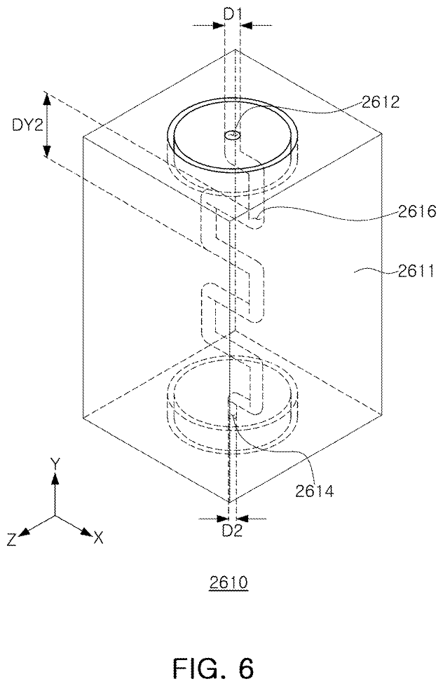

Referring to FIG. 6, a discharge suppressor 2610 according to an example embodiment has a body portion 2611, a gas discharge port 2612 may be provided on an upper surface of the body portion 2611, a gas supply port 2614 may be provided on a lower surface of the body portion 2611, and a gas supply flow path 2616 connecting the gas supply port 2614 and the gas discharge port 2612 may be formed inside the body portion 2611. Compared with the above-described embodiment, the discharge suppressor 2610 according to an example embodiment has a difference in that the gas supply flow path 2616 has a vertical portion and a horizontal portion. The horizontal portion of the gas supply flow path 2616 may be disposed to be parallel to an X-axis direction, a direction perpendicular to a direction of an electric field, and a vertical portion may be disposed along a Y-axis direction, a direction of an electric field. In this case, a length DY2 of the vertical portion of the gas supply flow path 2616 may be configured to a have a substantial length DY2 of 5 mm or less. Accordingly, it is possible to prevent electrons included in the heat transfer gas flowing along the gas supply flow path 2616 from being accelerated along a movement path exceeding 5 mm in the direction of the electric field.

The gas supply flow path 2616 according to an example embodiment may be formed so that a diameter thereof gradually decreases from an upper portion to a lower portion. Accordingly, a diameter D1 of the gas discharge port 2612 may be larger than a diameter D2 of the gas supply port 2614.

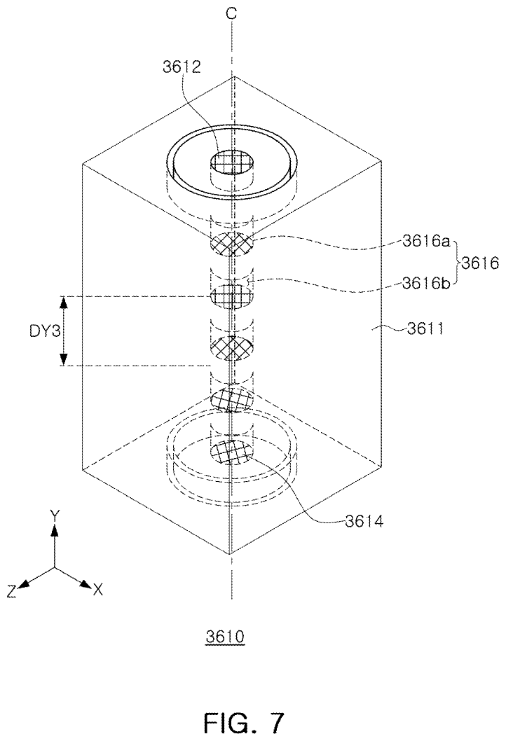

Referring to FIG. 7, a discharge suppressor 3610 according to an example embodiment has a body portion 3611, a gas discharge port 3612 may be provided on an upper surface of the body portion 3611, and a gas supply flow path 3616 connecting a gas supply port 3614 and the gas discharge port 3612 may be formed inside the body portion 3611. Compared with the above-described embodiment, there is a difference in that the discharge suppressor 3610 of an example embodiment has a plurality of mesh structures 3616a formed in an internal space of the gas supply flow path 3616. The gas supply flow path 3616 may have a structure in which the mesh structure 3616a and a space portion 3616b are alternately disposed in the Y-direction (i.e., the electric field direction). Accordingly, the internal space of the gas supply flow path 3616 may be partitioned by a plurality of mesh structures 3616a. In this case, the plurality of mesh structures 3616a may have substantially the same size as each other, and may be disposed to be parallel to each other. In addition, the plurality of mesh structures 3616a may be disposed to overlap with respect to substantially the same central axis C.

The plurality of mesh structures 3616a formed in the gas supply flow path 3616 have an advantage of shortening the vertical movement path of the heat transfer gas. Accordingly, while the gas supply flow path 3616 is formed to be elongated in the direction of the electric field, there is an effect that the discharge phenomenon is prevented.

In this case, a length DY3 between an upper surface of any one of the mesh structures 3616a and a lower surface of a mesh structure 3616a disposed therebelow may be configured to have a substantial length of 5 mm or less. Accordingly, it is possible to prevent electrons included in the heat transfer gas flowing through the gas supply flow path 3616 from being accelerated along a movement path exceeding 5 mm in the direction of the electric field.

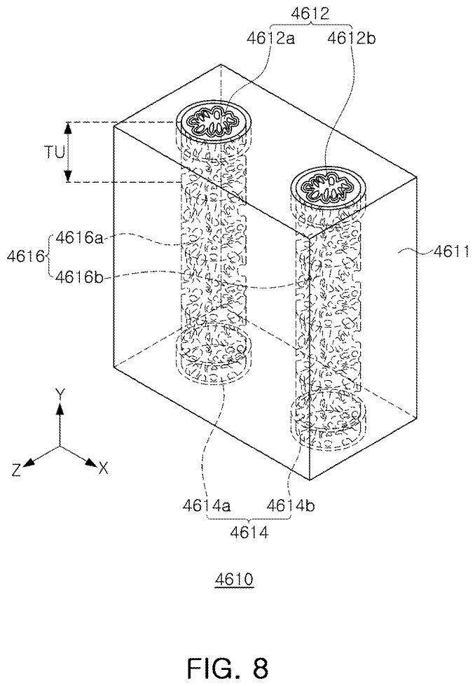

Referring to FIG. 8, a discharge suppressor 4610 according to an example embodiment has a body portion 4611, a gas discharge port 4612 may be provided on an upper surface of the body portion 4611, and a gas supply flow path 4616 connecting a gas supply port 4614 and the gas discharge port 4612 may be formed inside the body portion 4611. The gas supply port 4614 according to an example embodiment may include a first gas supply port 4614a and a second gas supply port 4614b. The gas discharge port 4612 of an example embodiment may include a first gas discharge port 4612a and a second gas discharge port 4612b. The gas supply flow path 4616 according to an example embodiment may include a first gas supply flow path 4616a and a second gas supply flow path 4616b. Compared with the above-described embodiment, there is a difference in that the gas supply flow path 3616 of the discharge suppressor 4610 according an example embodiment has a porous structure. The porous structure may be implemented by forming an inner wall of the gas supply flow path 4616 to form a triply periodic minimal surface. In this, the gas supply flow path 4616 may have a structure in which unit curved surfaces TU constituting a triply periodic minimum curved surface are stacked in the direction of the electric field.

The gas supply flow path 4616 having a porous structure has an advantage of making a movement path of the heat transfer gas flowing through the gas supply flow path 4616 irregularly. When the movement path of the heat transfer gas flowing through the gas supply flow path 4616 becomes irregular, the vertical movement path becomes very short, so that there is an effect that a discharge phenomenon is prevented while forming the gas supply flow path 4616 to be elongated in the direction of the electric field.

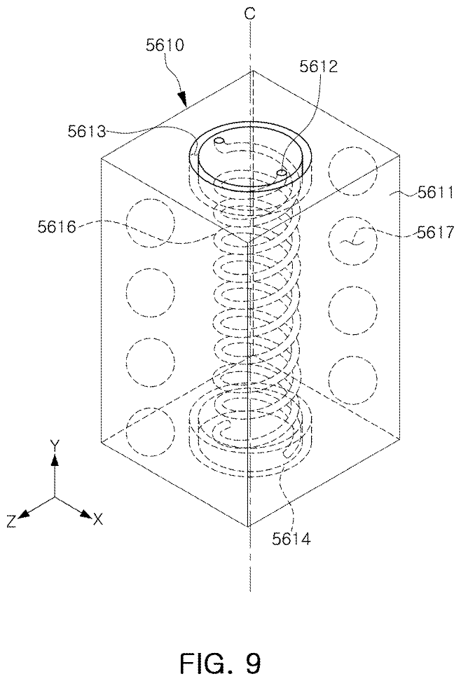

Referring to FIG. 9, a discharge suppressor 5610 according to an example embodiment has a body portion 5611, a gas discharge port 5612 may be provided on an upper surface of the body portion 5611, a gas supply port 5614 may be provided on a lower surface of the body portion 5611, and a gas supply flow path 5616 connecting the gas supply port 5614 and the gas discharge port 5612 may be formed in the body portion 5611. Compared with the above-described embodiment, there is a difference in that the discharge suppressor 5610 according to an example embodiment further has pores 5617 in the body portion 5611. The pores 5617 may form an empty space inside the body portion 5611, thereby reducing heat transfer between the lower electrode 520 and the conductive supporter 550. Accordingly, temperature control of the lower electrode 520 may be facilitated, and dew condensation may be prevented from occurring in the lower electrode 520.

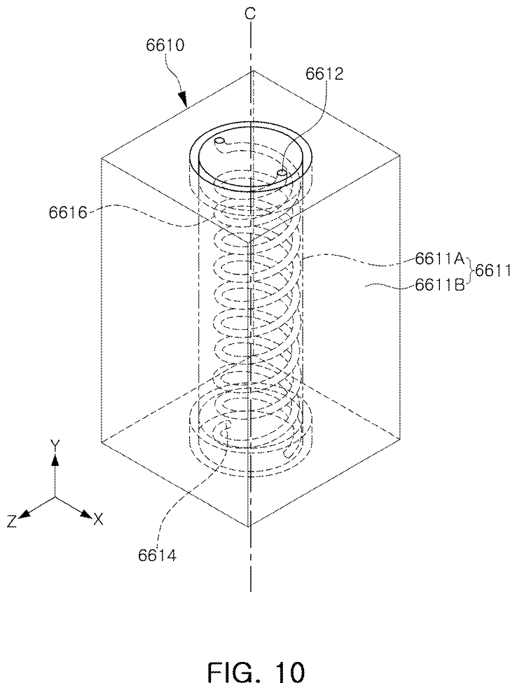

Referring to FIG. 10, a discharge suppressor 6610 according to an example embodiment has a body portion 6611, a gas discharge port 6612 may be provided on an upper surface of the body portion 6611, a gas supply port 6614 may be provided on a lower surface of the body portion 6611, and a gas supply flow path 6616 connecting the gas supply port 6614 and the gas discharge port 6612 may be formed inside the body portion 6611. Compared with the above-described embodiment, in the discharge suppressor 6610 according to an example embodiment, there is a difference in that the body portion 6611 includes a first region 6611A and a second region 6611B, wherein the first region 6611A and the second region 6611B are formed of a different material. For example, the first region 6611A may be a region in which the gas supply flow path 6616 is disposed, and the second region 6611B may be a region surrounding the first region 6611A. For example, the first region 6611A and the second region 6611B may be formed of a material having a different dielectric constant. Accordingly, in an example embodiment, the dielectric constant of the discharge suppressor 6610 can be adjusted, and thereby, impedance of the process chamber 100 can be adjusted.

By way of summation and review, when a semiconductor substrate is etched using a plasma processing apparatus, to manufacture a semiconductor device, the semiconductor substrate must be maintained at an appropriate temperature for an etching reaction to occur. To this end, a method of forming a microcavity in an electrostatic chuck supporting the semiconductor substrate and supplying heat transfer gas for controlling the temperature of the semiconductor substrate may be used. In a process of supplying the heat transfer gas to the microcavity, the heat transfer gas must pass through a lower electrode of the plasma processing apparatus and a grounded conductive member (between which an electric field is formed). However, when the heat transfer gas moves more than a predetermined length in a direction in which an electric field is formed, a discharge phenomenon may occur, which may damage the plasma processing apparatus.

In contrast, embodiments provide a plasma processing apparatus in which a discharge phenomenon is suppressed. That is, as set forth above, according to an embodiments, by forming a discharge suppressor disposed on a gas supply flow path to which heat transfer gas is supplied by 3D printing, it is possible to prevent discharge from occurring in a micro-gap of the discharge suppressor.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A plasma processing apparatus, comprising:
a process chamber configured to accommodate a substrate processing;
an electrostatic chuck in the process chamber and configured to support the substrate, the electrostatic chuck having a microcavity configured to store a heat transfer gas;
a lower electrode in contact with a lower surface of the electrostatic chuck;
a high-frequency power supply configured to applying high-frequency power to the lower electrode;
a conductive supporter spaced apart from a lower portion of the lower electrode and grounded thereto;
a gas supply line configured to supply the heat transfer gas; and
a three-dimensionally printed discharge suppressor between the lower electrode and the conductive supporter, the discharge suppressor including a gas supply flow path that is part of the gas supply line and connecting an upper surface and a lower surface of the discharge suppressor, and the gas supply flow path having a space portion with a length of 5 mm or less in a direction of an electric field formed by the high-frequency power.

2. The plasma processing apparatus as claimed in claim 1, wherein the gas supply flow path has a seamless inner wall.

3. The plasma processing apparatus as claimed in claim 2, wherein the gas supply flow path includes first and second gas supply flow paths, the first and second gas supply flow paths having a double helix shape together.

4. The plasma processing apparatus as claimed in claim 3, wherein a rotational radius of the double helix shape is gradually decreasing from the upper surface to the lower surface of the discharge suppressor.

5. The plasma processing apparatus as claimed in claim 1, wherein the gas supply flow path has a diameter gradually decreasing from the upper surface to the lower surface of the discharge suppressor.

6. The plasma processing apparatus as claimed in claim 1, wherein an inner wall of the gas supply flow path has a triply periodic minimal surface.

7. The plasma processing apparatus as claimed in claim 1, wherein:
the gas supply flow path extends in the direction of the electric field, and
an internal space of the gas supply flow path is partitioned by a plurality of mesh structures.

8. The plasma processing apparatus as claimed in claim 7, wherein the plurality of mesh structures are parallel to each other.

9. The plasma processing apparatus as claimed in claim 7, wherein the plurality of mesh structures have a same size as each other.

10. The plasma processing apparatus as claimed in claim 9, wherein the plurality of mesh structures overlap each other with respect to a same central axis.

11. The plasma processing apparatus as claimed in claim 1, wherein the heat transfer gas is helium gas.

12. The plasma processing apparatus as claimed in claim 1, wherein the microcavity overlaps the substrate.

13. The plasma processing apparatus as claimed in claim 1, wherein the discharge suppressor includes an insulating material.

14. The plasma processing apparatus as claimed in claim 13, wherein the insulating material includes polyether ether ketone.

15. A plasma processing apparatus, comprising:
an electrostatic chuck configured to support a substrate;
a lower electrode below the electrostatic chuck;
a high-frequency power supply configured to apply high-frequency power to the lower electrode;
a conductive supporter spaced apart from a lower portion of the lower electrode and grounded thereto;
a gas supply line configured to supply a heat transfer gas to the electrostatic chuck; and
a three-dimensionally printed discharge suppressor between the lower electrode and the conductive supporter, the discharge suppressor including a gas supply flow path having a seamless inner wall and being part of the gas supply line, and the discharge suppressor being configured to suppress discharge of the heat transfer gas.

16. The plasma processing apparatus as claimed in claim 15, wherein:
the heat transfer gas is helium gas, and
the gas supply flow path has a space portion having a length of 5 mm or less in a direction of an electric field formed by the high-frequency power.

17. The plasma processing apparatus as claimed in claim 15, wherein the gas supply flow path has a space portion having a length of 5 mm or less in a direction of an electric field formed by the high-frequency power.

18. A plasma processing apparatus, comprising:
a process chamber;
an upper electrode in a top portion of the process chamber;
a lower electrode in a lower portion of the process chamber, the lower electrode corresponding to the upper electrode;
an electrostatic chuck supporting a substrate and having a microcavity in which a heat transfer gas is stored, the electrostatic chuck being on the lower electrode;
a conductive supporter spaced apart from a lower portion of the lower electrode and grounded thereto;
a heat transfer gas supply path configured to supply the heat transfer gas to the microcavity; and
a discharge suppressor between the lower electrode and the conductive supporter, the discharge suppressor including a body portion and a gas supply flow path through the body portion, the gas supply flow path being part of the heat transfer gas supply path, and the gas supply flow path having a space portion with a length of 5 mm or less in a direction of an electric field.

19. The plasma processing apparatus as claimed in claim 18, wherein the discharge suppressor is molded by three dimensional printing, and the gas supply flow path has a seamless inner wall.

20. The plasma processing apparatus as claimed in claim 18, wherein the heat transfer gas is helium gas.
